(19) United States
(12) Patent Application Publication
(10) Pub. No.: US 2011/0079274 A1
(43) Pub. Date: Apr. 7, 2011

(54) PHOTOELECTRIC CONVERSION DEVICE

(76) Inventors: Moon-Sung Kang, Yongin-si (KR); Ji-Won Lee, Yongin-si (KR); Su-Bin Song, Yongin-si (KR); Joo-Sik Jung, Yongin-si (KR)

(21) Appl. No.: 12/873,227

(22) Filed: Aug. 31, 2010

Related U.S. Application Data
(60) Provisional application No. 61/249,126, filed on Oct. 6, 2009.

(51) Int. Cl. H01L 31/04

(52) U.S. Cl. 136/252

(57) ABSTRACT

A photoelectric conversion device designed according to a ratio of a line width to a pitch of a grid collector electrode is provided. The photoelectric conversion device includes a first substrate, a second substrate facing the first substrate, and a first electrode between the first substrate and the second substrate, the first electrode including a first grid electrode. A first ratio (W/P) of a line width of the first grid electrode to a pitch of the first grid electrode is configured in accordance with a photoelectric conversion efficiency of the photoelectric conversion device, thereby the photoelectric conversion device may have improved photoelectric conversion efficiency.

### CROSS-REFERENCE TO RELATED APPLICATIONS

This application claims priority to and the benefit of U.S. Provisional Application No. 61/249,126, filed on Oct. 6, 2009, in the United States Patent and Trademark Office, the disclosure of which is incorporated herein in its entirety by reference.

### BACKGROUND

1. Field

An aspect of an embodiment of the present invention relates to a photoelectric conversion device.

2. Description of the Related Art

Photoelectric conversion devices convert light into electric energy. From among such devices, solar cells utilizing sunlight have attracted attention as an alternative energy source to fossil fuels.

Among the solar cells, wafer-based crystalline silicon solar cells using a P-N semiconductor junction are widely used. However, the manufacturing costs of wafer-based crystalline silicon solar cells are high because they are formed of a high purity semiconductor material.

Unlike silicon solar cells, dye-sensitized solar cells include a photosensitive dye that receives visible light and generates excited electrons, a semiconductor material that receives the excited electrons, and an electrolyte that reacts with the electrons returning from an external circuit. Since dye-sensitized solar cells have much higher photoelectric conversion efficiency than other conventional solar cells, the dye-sensitized solar cells are viewed as the next generation solar cells.

### SUMMARY

An aspect of one or more embodiments of the present invention relates to a photoelectric conversion device with improved photoelectric conversion efficiency.

According to one embodiment of the present invention, a photoelectric conversion device includes: a first substrate; a second substrate facing the first substrate; and a first electrode between the first substrate and the second substrate, the first electrode including a first grid electrode. A first ratio (W/P) of a line width of the first grid electrode to a pitch of the first grid electrode is configured in accordance with a photoelectric conversion efficiency of the photoelectric conversion device.

The first grid electrode includes a plurality of first finger electrodes, and the line width of the first grid electrode may be a width of each of the first finger electrodes and the pitch of the first grid electrode may be a distance between adjacent ones of the first finger electrodes.

The first ratio (W/P) may be between about 0.009 and about 0.1. The first ratio (W/P) may be at least about 0.0125. The line width may be at least about 0.5 mm.

The first ratio (W/P) may not be greater than about 0.0625.

The first ratio (W/P) may be between about 0.0125 and about 0.0625.

The photoelectric conversion device may further include a second electrode between the first electrode and the second substrate, the second electrode including a second grid electrode. A second ratio (W/P) of a line width of the second grid electrode to a pitch of the second grid electrode is configured in accordance with the photoelectric conversion efficiency of the photoelectric conversion device.

The line width of the second grid electrode may be at least about 0.5 mm.

The second ratio (W/P) may be between about 0.009 and about 0.1.

The second ratio (W/P) may not be greater than about 0.0625.

The second grid electrode may include a plurality of second finger electrodes, and the line width of the second grid electrode may be a width of each of the second finger electrodes and the pitch of the second grid electrode may be a distance between adjacent ones of the second finger electrodes.

The photoelectric conversion may further include a semiconductor layer between the first electrode and the second electrode, the semiconductor layer including a photosensitive dye.

The photoelectric conversion may further include a semiconductor layer on the first electrode, the semiconductor layer including a photosensitive dye.

The first electrode may further include a transparent conductive layer between the first substrate and the first grid electrode.

The first grid electrode may include a metal material.

According to another embodiment of the present invention, a photoelectric conversion device includes: a first substrate; a second substrate facing the first substrate; a first electrode between the first substrate and the second substrate, the first electrode including a first grid electrode; and a second electrode between the first electrode and the second substrate, the second electrode including a second grid electrode. A first ratio (W/P) of a line width of the first grid electrode to a pitch of the first grid electrode and a second ratio (W/P) of a line width of the second grid electrode to a pitch of the second grid electrode are configured in accordance with a photoelectric conversion efficiency of the photoelectric conversion device.

The first ratio and/or the second ratio may be between about 0.009 and about 0.1.

The first ratio and/or the second ratio may not be greater than about 0.0625.

According to another embodiment of the present invention, a method of fabricating a photoelectric conversion device including a first substrate and a second substrate facing the first substrate, is provided. The method includes: patterning a first grid electrode between the first substrate and the second substrate, wherein the patterning of the first grid electrode includes configuring a ratio (W/P) of a line width of the first grid electrode to a pitch of the first grid electrode in accordance with a photoelectric conversion efficiency of the photoelectric conversion device.

### BRIEF DESCRIPTION OF THE DRAWINGS

Aspects of embodiments of the present invention will become apparent and more readily appreciated from the following description of the embodiments, taken in conjunction with the accompanying drawings of which:

FIG. 1 is a cross-sectional view of a photoelectric conversion device according to an embodiment of the present invention;

FIG. 2 is a plan view of a light receiving substrate of the photoelectric conversion device of FIG. 1 on which a photoelectrode is formed;

FIG. 3 is a circuit diagram for explaining a model of the photoelectrode of FIG. 2;

FIG. 4 is a circuit diagram for calculating one equivalent resistance from the model of the photoelectrode of FIG. 3;

FIG. 5 is a graph illustrating a relationship between the equivalent resistance of the photoelectrode and the line width of a grid electrode;

FIG. 6 is a graph illustrating a relationship between the aperture ratio of a light receiving substrate and a ratio of the line width of the grid electrode to the pitch of the grid electrode;

FIG. 7 is a graph illustrating a relationship between photoelectric conversion efficiency and the ratio between the line width of the grid electrode and the pitch of the grid electrode; and

FIG. 8 is a cross-sectional view of a photoelectric conversion device according to an embodiment of the present invention.

### DETAILED DESCRIPTION

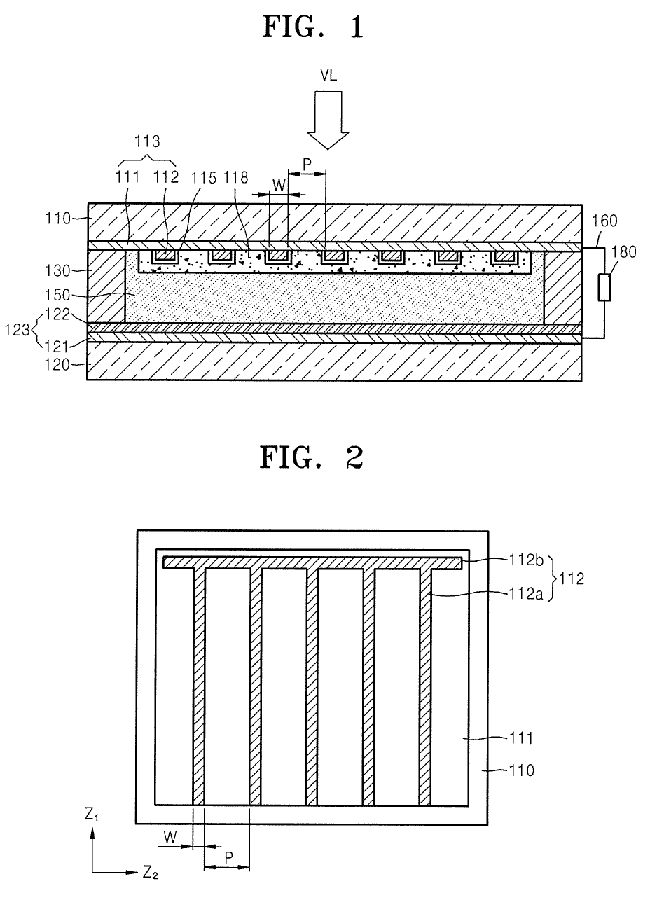

One or more embodiments of the present invention will now be described with reference to the attached drawings. FIG. 1 is a cross-sectional view of a photoelectric conversion device according to an embodiment of the present invention. Referring to FIG. 1, a light receiving substrate 110 on which a photoelectrode 113 is formed and a counter substrate 120 on which a counter electrode 123 is formed face each other. A semiconductor layer 118 adsorbed with a photosensitive dye that is excited by light VL is formed on the photoelectrode 113. An electrolyte layer 150 is disposed between the semiconductor layer 118 and the counter electrode 123.

The light receiving substrate 110 and the counter substrate 120 are attached to each other using a sealing material 130 such that an interval is located therebetween. An electrolyte solution used for the electrolyte layer 150 may be filled between the light receiving substrate 110 and the counter substrate 120. The photoelectrode 113 and the counter electrode 123 are electrically connected to each other using a wire 160 through an external circuit 180. In a module in which a plurality of photoelectric conversion devices are connected in series or in parallel, photoelectrodes and counter electrodes of the plurality of photoelectric conversion devices may be connected in series or in parallel, and both ends of connected photoelectrodes and/or counter electrodes may be connected to the external circuit 180.

The light receiving substrate 110 may be formed of a transparent material, for example, a material having a high light transmittance. For example, the light receiving substrate 110 may be a glass substrate or a resin film substrate. Since a resin film usually has flexibility, the resin film may be applied to devices requiring flexibility.

The photoelectrode 113 may include a transparent conductive layer 111 and a grid electrode 112 formed in a mesh or grid pattern on the transparent conductive layer 111. The transparent conductive layer 111 is formed of a material having transparency and electrical conductivity, for example, a transparent conductive oxide such as indium tin oxide (ITO), fluorine tin oxide (FTO), or antimony-doped tin oxide (ATO). The grid electrode 112 reduces the electrical resistance of the photoelectrode 113, and functions as a collector wire that collects electrons generated by photoelectric conversion and provides a current path having a low resistance. For example, the grid electrode 112 may be formed of a metal material having high electrical conductivity, such as gold (Ag), silver (Au), or aluminum (Al), and may be patterned in a mesh or grid fashion.

The photoelectrode 113 functions as a cathode of the photoelectric conversion device and may have a high aperture ratio. Since light VL incident through the photoelectrode 113 excites the photosensitive dye adsorbed into the semiconductor layer 118, the photoelectric conversion efficiency may be improved when the amount of incident light VL is increased. The term “aperture ratio” is a ratio of an effective light transmitting area to the overall area of the light receiving substrate 110 on which the photoelectrode 113 is coated or located. Since the grid electrode 112 is usually formed of an opaque material, e.g., a metal material, the aperture ratio decreases as the area of the grid electrode 112 increases. Since a line width W of the grid electrode 112 limits the effective light transmitting area, the line width W of the grid electrode 112 should be small. However, since the grid electrode 112 is used to reduce the electrical resistance of the photoelectrode 113, for example, a pitch P of the grid electrode 112, which is an interval between adjacent grid electrode segments (or teeth) of the grid electrode 112 made by the mesh pattern, should be small as well in order to compensate for an increase in the electrical resistance of the photoelectrode 113 caused when the line width W of the grid electrode 112 is small.

A protective layer 115 may be further formed on an outer surface of the grid electrode 112. The protective layer 115 prevents the grid electrode 112 from being damaged, for example, from being eroded, when the grid electrode 112 contacts and reacts with the electrolyte layer 150. The protective layer 115 may be formed of a material that does not react with the electrolyte layer 150, for example, a curable resin material.

The semiconductor layer 118 may be formed of a metal oxide such as Cd, Zn, In, Pb, Mo, W, Sb, Ti, Ag, Mn, Sn, Zr, Sr, Ga, Si, or Cr, and other suitable metal oxides. The semiconductor layer 118 may increase the photoelectric conversion efficiency by adsorbing the photosensitive dye. For example, the semiconductor layer 118 may be formed by coating a paste of semiconductor particles having a particle diameter between 5 and 1000 nm on the light receiving substrate 110 on which the photoelectrode 113 is formed and applying heat or pressure to the resultant structure.

The photosensitive dye adsorbed into the semiconductor layer 118 absorbs light VL passing through the light receiving substrate 110, so that electrons of the photosensitive dye are excited from a ground state. The excited electrons are transferred to the conduction band of the semiconductor layer 118 through electrical contact between the photosensitive dye and the semiconductor layer 118, to the semiconductor layer 118, and to the photoelectrode 113, and are discharged to the outside through the photoelectrode 113, thereby forming a driving current for driving the external circuit 180.

For example, the photosensitive dye adsorbed into the semiconductor layer 118 may consist of molecules that absorb light VL and excite electrons so as to allow the excited electrons to be rapidly moved to the semiconductor layer 118. The photosensitive dye may be any one of liquid type, semi-solid gel type, and solid type photosensitive dyes. For example, the photosensitive dye adsorbed into the semiconductor layer 118 may be a ruthenium-based photosensitive dye. The semiconductor layer 118 adsorbed with the photosensitive dye may be obtained by dipping the light receiving substrate 110 on which the semiconductor layer 118 is formed in a solution including the photosensitive dye.

The electrolyte layer 150 may be formed of a redox electrolyte including reduced/oxidized (R/O) couples. The electrolyte layer 150 may be formed of any one of solid type, gel type, and liquid type electrolytes.

The counter substrate 120 facing the light receiving substrate 110 is not necessarily transparent. However, in order to increase photoelectric conversion efficiency, the counter substrate 120 may be formed of a transparent material so that light VL is received on both sides of the photoelectric conversion device, and may be formed of the same material as that of the light receiving substrate 110. For example, if the photoelectric conversion device is installed as an integrated photovoltaic system in a building structure, e.g., a window frame, both sides of the photoelectric conversion device may be transparent so that light VL is not being blocked from entering into the inside of a building.

The counter electrode 123 may include a transparent conductive layer 121 and a catalyst layer 122 formed on the transparent conductive layer 121. The transparent conductive layer 121 is formed of a material having transparency and electrical conductivity, for example, a transparent conductive oxide such as ITO, FTO, or ATO. The catalyst layer 122 is formed of a reduction catalyzing material for providing electrons to the electrolyte layer 150. For example, the catalyst layer 122 may include a metal such as platinum (Pt), gold (Ag), silver (Au), copper (Cu), or aluminum (Al), a metal oxide such as a tin oxide, or a carbon-based material such as graphite.

The counter electrode 123 functions as an anode of the photoelectric conversion device, and also as a reduction catalyst for providing electrons to the electrolyte layer 150. The photosensitive dye adsorbed into the semiconductor layer 118 absorbs light VL to excite electrons, and the excited electrons are discharged to the outside of the photoelectric conversion device through the photoelectrode 113. The photosensitive dye losing the electrons receive electrons generated by oxidization of the electrolyte layer 150, which is to be reduced again, and the oxidized electrolyte layer 150 is reduced again by electrons passing through the external circuit 180 and reaching the counter electrode 123, thereby completing the operation of the photoelectric conversion device.

FIG. 2 is a plan view of the light receiving substrate 110 on which the photoelectrode 113 is formed. Referring to FIG. 2, the grid electrode 112 which is patterned in a shape is formed on the transparent conductive layer 111. The grid electrode 112 may have a comb shape with a plurality of fingers (or teeth) 112a extending in stripes in one direction Z₁, and a bus bar 112b extending to cross the fingers 112a and adapted to collect electrons from the fingers 112a and discharge the collected electrons to the outside of the photoelectric conversion device. Reference symbols P and W denote the pitch and the line width of the grid electrode 112, respectively.

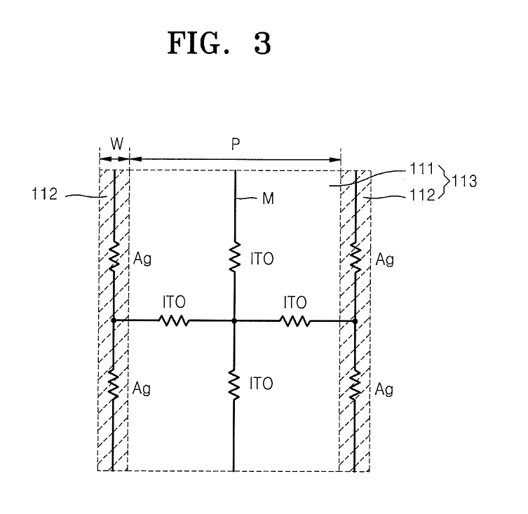

FIG. 3 is a circuit diagram for explaining a model of the photoelectrode 113 of FIG. 2. Referring to FIG. 3, the photoelectrode 113 includes a grid-type current path M, and resistors ITO and Ag located in the current path M. The current path M is a path through which electrons generated by photoelectric conversion pass through the transparent conductive layer 111 and move to the grid electrode 112. The current path M simplifies the network structure of the grid electrode segments of the grid electrode 112 and the transparent conductive layer 111 between the grid electrode segments of the grid electrode 112. The resistors ITO and Ag indicate resistor components of the grid electrode 112 and the transparent conductive layer 111. For example, the resistivity of the resistor ITO corresponds to the transparent conductive layer 111, and the resistivity of the resistor Ag corresponds to the grid electrode 112. The electrical resistance of each of the resistors ITO and Ag may be calculated by multiplying each resistivity by the pitch P or the line width W of the grid electrode 112. For example, the length of the resistor ITO corresponding to the transparent conductive layer 111 varies according to the pitch P of the grid electrode 112, and the electrical resistance of the resistor ITO is determined by multiplying the resistivity of the resistor ITO by the length of the resistor ITO. Also, the width of the resistor Ag corresponding to the grid electrode 112 varies according to the line width W of the grid electrode 112, and the electrical resistance of the resistor Ag is determined by multiplying the resistivity of the resistor Ag by the width of the resistor Ag.

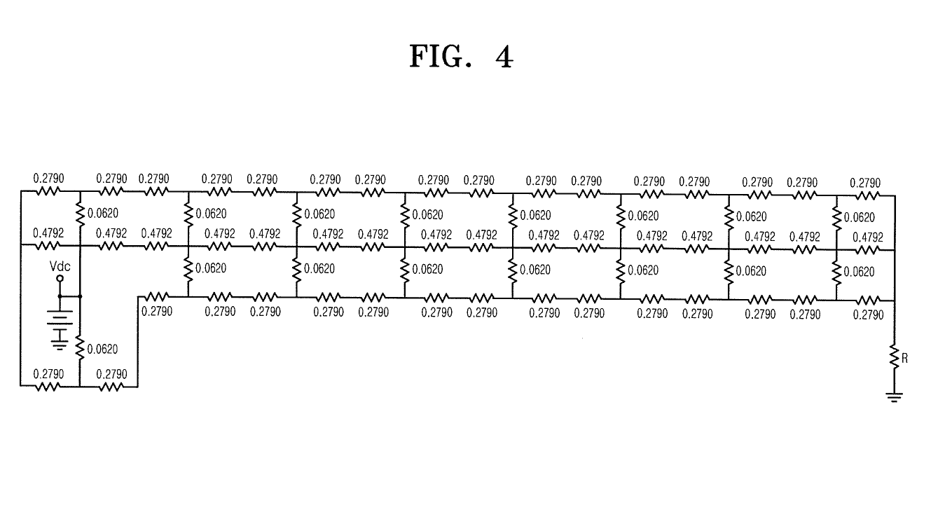

In FIG. 3, when the light receiving substrate 110 on which the photoelectrode 113 is formed has an area of 100 mm×100 mm, the equivalent resistance of the photoelectrode 113 is calculated while varying the pitch P and the line width W of the grid electrode 112 and the transparent conductive layer 111 while fixing the thickness of the grid electrode 112 to a certain value. FIG. 4 is a circuit diagram for calculating one equivalent resistance from the model of the photoelectrode 113 of FIG. 3 under a given condition, according to one embodiment of the present invention. For example, the equivalent resistance of the photoelectrode 113 may be calculated using a current value that is obtained by inputting the simulation model of the photoelectrode 113 into a program such as OrCAD-PSpice or other suitable programs, applying a voltage Vdc of 1V to one node, and connecting an external unit having a load resistance R of 1Ω between the model of the photoelectrode 113 and the ground.

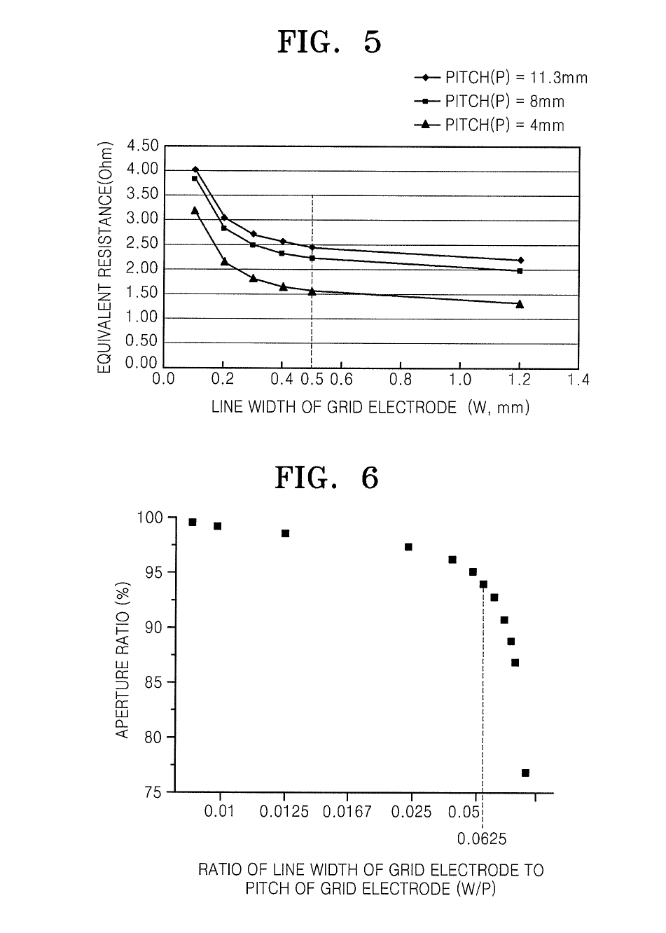

FIG. 5 is a graph illustrating a relationship between the equivalent resistance of the photoelectrode 113 and the line width W of the grid electrode 112, according to one embodiment of the present invention. In FIG. 5, the pitch P of the grid electrode 112 is 4 mm, 8 mm, and 11.3 mm. Referring to FIG. 5, the equivalent resistance of the photoelectrode 113 increases as the line width W of the grid electrode 112 decreases. In particular, the equivalent resistance sharply increases when the line width W is smaller than 0.5 mm. Accordingly, the line width W may be limited to a value of at least greater than 0.5 mm.

As illustrated in FIG. 5, in order to increase the collection efficiency and reduce the electrical resistance of the photoelectrode 113, the line width W of the grid electrode 112 should be increased. In contrast, in order to increase the aperture ratio of the light receiving substrate 110 and increase an effective light transmitting area, the line width W of the grid electrode 112 that is opaque should be decreased. Accordingly, the line width W of the grid electrode 112 is appropriately determined so as to increase photoelectric conversion efficiency.

The design of the grid electrode 112 directly affects the aperture ratio of the light receiving substrate 110. For example, when the light receiving substrate 110 has a fixed area, the pitch P and the line width W of the grid electrode 112 may determine the aperture ratio of the light receiving substrate 110. FIG. 6 is a graph illustrating a relationship between the aperture ratio of the light receiving substrate 110 and a ratio W/P of the line width W of the grid electrode 112 to the pitch P of the grid electrode 112 when the light receiving substrate 110 has a fixed area, according to one embodiment of the present invention. In FIG. 6, the ratio W/P is set as a design parameter.

Referring to FIG. 6, the aperture ratio of the light receiving substrate 110 varies according to the ratio W/P. That is, the aperture ratio increases as the ratio W/P decreases, and the aperture ratio decreases as the ratio W/P increases. In other words, as the line width W of the grid electrode 112 decreases and the pitch P increases, the aperture ratio of the light receiving substrate 110 increases. On the contrary, as the line width W of the grid electrode 112 increases and the pitch P decreases, the aperture ratio decreases. In particular, since the aperture ratio of the light receiving substrate 110 drastically decreases when the ratio W/P is about 0.0625, the ratio W/P may be limited to a suitable value smaller than 0.0625.

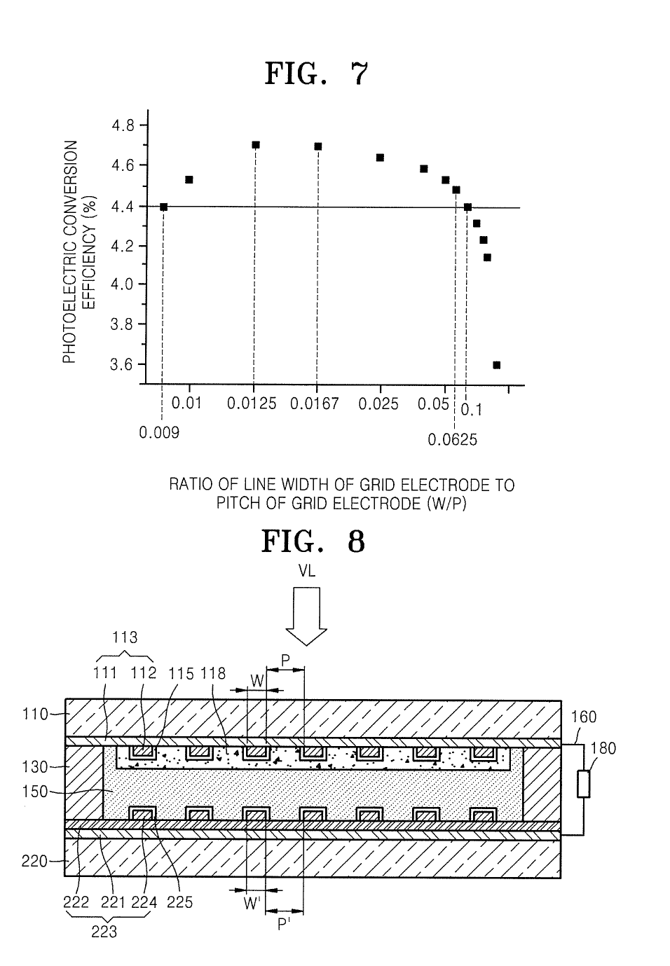

FIG. 7 is a graph illustrating a relationship between photoelectric conversion efficiency η and the ratio W/P between the line width W of the grid electrode 112 and the pitch P of the grid electrode 112. The photoelectric conversion efficiency q may be calculated using Equation 1 below by using the intensity of incident light Po (mW/cm2) that is an input to the photoelectric conversion device, an open voltage Voc (V) at an output terminal of the photoelectric conversion device, a shortcut current density Jsc (mA/cm2), and a fill-factor FF.

η=100×(Voc×Jsc×FF)/Po Equation 1

Referring to FIG. 7, the photoelectric conversion efficiency varies according to the ratio W/P between the line width W of the grid electrode 112 and the pitch P of the grid electrode 112. In FIG. 7, the photoelectric conversion efficiency is the highest, about 4.7%, when the ratio W/P is 0.0125, and the photoelectric conversion efficiency decreases from the peak of 4.7%. When the ratio W/P is greater than 0.0125, the photoelectric conversion efficiency decreases as the ratio W/P increases. Such a profile is similar to that of the graph of FIG. 6. This is because the aperture ratio of the light receiving substrate 110 directly affects the photoelectric conversion efficiency so that the photoelectric conversion efficiency varies depending on the aperture ratio. In one embodiment, since the photoelectric conversion efficiency drastically decreases when the ratio W/P is further increased from about 0.1, the ratio W/P may be limited to a suitable value smaller than or equal to 0.1, for example, 0.0625.

When the ratio W/P is smaller than 0.0125, the photoelectric conversion efficiency drastically decreases as the ratio W/P decreases. This is because if the ratio W/P is below an appropriate level, the electrical resistance of the photoelectrode 113 increases, thereby limiting the photoelectric conversion efficiency. That is, when the ratio W/P is low, the line width W of the grid electrode 112 is small and the pitch P is large, therefore, the area of the grid electrode 112 is reduced and the electrical resistance of the photoelectrode 113 is increased. Accordingly, the ratio W/P may be limited to a value equal to or greater than 0.009, for example, 0.0125.

In conclusion, the ratio W/P between the line width W of the grid electrode 112 and the pitch P of the grid electrode 112 may be determined to satisfy 0.009≦W/P≦0.1, in one embodiment, 0.0125≦W/P≦0.0625. If the ratio W/P is greater than the upper limit of 0.1, the aperture ratio of the light receiving substrate 110 is limited, thereby lowering the photoelectric conversion efficiency. If the ratio W/P is smaller than the lower limit of 0.009, the electrical resistance of the photoelectrode 113 is increased, thereby lowering the photoelectric conversion efficiency.

FIG. 8 is a cross-sectional view of a photoelectric conversion device according to another embodiment of the present invention. Referring to FIG. 8, the light receiving substrate 110 on which the photoelectrode 113 is formed, the semiconductor layer 118 adsorbed with a photosensitive dye, the electrolyte layer 150, and the counter substrate 220 on which the counter electrode 223 is formed are sequentially disposed in a direction in which light VL is incident. The photoelectrode 113 includes the transparent conductive layer 111 and the grid electrode 112 formed in a mesh pattern or grid pattern on the transparent conductive layer 111. The counter electrode 223 facing the photoelectrode 113 includes a transparent conductive layer 221, a catalyst layer 222 formed on the transparent conductive layer 221, and a grid electrode 224 formed in a mesh pattern or grid pattern on the catalyst layer 222.

The photoelectric conversion device of FIG. 8 is different from the photoelectric conversion device of FIG. 1 in that the grid electrode 224 is formed on the counter electrode 223 in addition to the grid electrode 112 formed on the photoelectrode 113. The grid electrode 224 reduces the electrical resistance of the counter electrode 223, and provides a current path having a low resistance for collecting electrons passing through the external circuit 180 and reaching the counter electrode 223 and sending the electrons to the electrolyte layer 150. For example, the grid electrode 224 may be formed of a metal material having high electrical conductivity, such as gold (Ag), silver (Au), or aluminum (Al), or other suitable metals, and may be patterned in a mesh fashion.

A protective layer 225 may be further formed on an outer surface of the grid electrode 224. The protective layer 225 prevents the grid electrode 224 from being damaged, for example, from being eroded when the grid electrode 224 contacts and reacts with the electrolyte layer 150. The protective layer 225 may be formed of a material that does not react with the electrolyte layer 150, for example, a curable resin material.

The above disclosure about the photoelectric conversion efficiency, the aperture ratio, and the electrical characteristics of the photoelectrode 113 of FIGS. 5 through 7 may be applied to the counter electrode 223 as well as the photoelectrode 113. That is, according to the disclosure described with reference to FIGS. 5 through 7, the counter electrode 223 is designed to improve the photoelectric conversion efficiency, and a pitch P′ and a line width W′ of the grid electrode 224 included in the counter electrode 223 may be appropriately determined.

According to the one or more embodiments of the present invention, an electrode for collecting electrons generated by photoelectric conversion is designed to improve photoelectric conversion efficiency. That is, the shape and arrangement of a grid electrode directly affecting the aperture ratio and resistance of a substrate is appropriately determined by a design parameter that corresponds to a relationship between the line width of a grid electrode and the pitch of the grid electrode. The design parameter set in a suitable range allows high photoelectric conversion efficiency, therefore, a photoelectric conversion device with high efficiency may be provided.

While the present invention has been particularly shown and described with reference to exemplary embodiments thereof, it will be understood by those of ordinary skill in the art that various changes in form and details may be made therein without departing from the spirit and scope as defined by the following claims and their equivalents.

What is claimed is:

1. A photoelectric conversion device comprising:
a first substrate;
a second substrate facing the first substrate; and
a first electrode between the first substrate and the second substrate, the first electrode comprising a first grid electrode,
wherein a first ratio (W/P) of a line width of the first grid electrode to a pitch of the first grid electrode is configured in accordance with a photoelectric conversion efficiency of the photoelectric conversion device.

2. The photoelectric conversion device of claim 1,
wherein the first grid electrode comprises a plurality of first finger electrodes, and
wherein the line width of the first grid electrode is a width of each of the first finger electrodes and the pitch of the first grid electrode is a distance between adjacent ones of the first finger electrodes.

3. The photoelectric conversion device of claim 1, wherein the photoelectric conversion efficiency is defined as:
η=100×(Voc×Jsc×FF)/Po
wherein η is the photoelectric conversion efficiency, Po is an intensity of incident light (mW/cm²) that is an input to the photoelectric conversion device, Voc is an open voltage (V) at an output terminal of the photoelectric conversion device, Jsc is a shortcut current density (mA/cm²), and FF is a fill-factor.

4. The photoelectric conversion device of claim 1, wherein the first ratio (W/P) is at least about 0.0125.

5. The photoelectric conversion device of claim 1, wherein the line width is at least about 0.5 mm.

6. The photoelectric conversion device of claim 1, wherein the first ratio (W/P) is between about 0.009 and about 0.1.

7. The photoelectric conversion device of claim 1, wherein the first ratio (W/P) is not greater than about 0.0625.

8. The photoelectric conversion device of claim 1, wherein the first ratio (W/P) is between about 0.0125 and about 0.0625.

9. The photoelectric conversion device of claim 1, further comprising:
a second electrode between the first electrode and the second substrate, the second electrode comprising a second grid electrode,
wherein a second ratio (W/P) of a line width of the second grid electrode to a pitch of the second grid electrode is configured in accordance with the photoelectric conversion efficiency of the photoelectric conversion device.

10. The photoelectric conversion device of claim 9, wherein the line width of the second grid electrode is at least about 0.5 mm.

11. The photoelectric conversion device of claim 9, wherein the second ratio (W/P) is between about 0.009 and about 0.1.

12. The photoelectric conversion device of claim 9, wherein the second ratio (W/P) is not greater than about 0.0625.

13. The photoelectric conversion device of claim 9,
wherein the second grid electrode comprises a plurality of second finger electrodes, and
wherein the line width of the second grid electrode is a width of each of the second finger electrodes and the pitch of the second grid electrode is a distance between adjacent ones of the second finger electrodes.

14. The photoelectric conversion device of claim 13, further comprising a semiconductor layer between the first electrode and the second electrode, the semiconductor layer comprising a photosensitive dye.

15. The photoelectric conversion device of claim 1, further comprising a semiconductor layer on the first electrode, the semiconductor layer comprising a photosensitive dye.

16. The photoelectric conversion device of claim 1, wherein the first electrode further comprises a transparent conductive layer between the first substrate and the first grid electrode.

17. The photoelectric conversion device of claim 1, wherein the first grid electrode comprises a metal material.

18. A photoelectric conversion device comprising:
a first substrate;
a second substrate facing the first substrate;
a first electrode between the first substrate and the second substrate, the first electrode comprising a first grid electrode; and
a second electrode between the first electrode and the second substrate, the second electrode comprising a second grid electrode,
wherein a first ratio (W/P) of a line width of the first grid electrode to a pitch of the first grid electrode and a second ratio (W/P) of a line width of the second grid electrode to a pitch of the second grid electrode are configured in accordance with a photoelectric conversion efficiency of the photoelectric conversion device.

19. The photoelectric conversion device of claim 18, wherein the first ratio and/or the second ratio is between about 0.009 and about 0.1.

20. The photoelectric conversion device of claim 18, wherein the first ratio and/or the second ratio is not greater than about 0.0625.
